(19) United States
(12) Patent Application Publication
(10) Pub. No.: US 2026/0004844 A1
(43) Pub. Date: Jan. 1, 2026

(54) END-OF-CYCLE SIGNAL GENERATION CIRCUIT AND METHOD

(71) Applicant: TAIWAN SEMICONDUCTOR MANUFACTURING COMPANY, LTD., Hsinchu (TW)

(72) Inventor: Sanjeev Kumar JAIN, Hsinchu (TW)

(21) Appl. No.: 18/760,589

(22) Filed: Jul. 1, 2024

(51) Int. Cl. G11C 11/419; G11C 7/22; G11C 11/418; H03K 3/037; H03K 19/20

(52) U.S. Cl. CPC G11C 11/419; G11C 7/222; G11C 11/418; H03K 3/037; H03K 19/20

(57) ABSTRACT

A signal generation circuit includes a loopback path and a signal generator including an inverter including an output terminal coupled to a first end of the loopback path, a transistor coupled between a second end of the loopback path and a power distribution node, a buffer including an input terminal configured to receive a clock signal, a first logic gate including a first input terminal coupled to the buffer input terminal, a second input terminal coupled to an output terminal of the buffer, and an output terminal coupled to an input terminal of the inverter and a gate of the transistor, and a second logic gate including a first input terminal coupled to the buffer input terminal, a second input terminal coupled to the second end of the loopback path, and an output terminal configured to output an output signal.

### BACKGROUND

The ongoing trend in miniaturizing integrated circuits (ICs) has resulted in progressively smaller devices which consume less power, yet provide more functionality at higher speeds than earlier technologies. Such miniaturization has been achieved through design and manufacturing innovations tied to increasingly strict specifications. In some cases, specifications are directed to timing of read and write operations in memory circuits such as multi-bank static random-access memory (SRAM) circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a memory circuit, in accordance with some embodiments.

FIG. 2 depicts memory circuit operating parameters, in accordance with some embodiments.

FIG. 3 is a block diagram of an end-of-cycle signal generation circuit, in accordance with some embodiments.

FIGS. 4A and 4B are a respective schematic diagram and depiction of operating parameters of an end-of-cycle signal generation circuit, in accordance with some embodiments.

FIGS. 4C and 4D are a respective schematic diagram and depiction of operating parameters of an end-of-cycle signal generation circuit, in accordance with some embodiments.

FIG. 5 is a flowchart of a method of operating a memory circuit, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, a signal generation circuit includes a loopback path and a signal generator including an inverter coupled to a first end of the loopback path, a transistor coupled between a second end of the loopback path and a power distribution node, a buffer configured to receive a clock signal, a first logic gate coupled to the buffer, inverter, and a gate of the transistor, and a second logic gate coupled to the buffer and the second end of the loopback path. The signal generator thereby includes the transistor and first logic gate configured as a loopback bypass circuit configured to cause the second logic gate to output a signal, e.g., an end-of-cycle signal of a memory circuit, including pulses having leading edges based on the clock signal and trailing edges based on an internal clock signal propagated through the loopback path.

Compared to other approaches, e.g., those in which a signal generator does not include a loopback bypass circuit, the signal generation circuit is thereby capable of maintaining output signal integrity and avoiding unintended circuit operations, e.g., double clocking in memory circuit read/write operations that can cause circuit malfunctions and increased power consumption by setting input latches to transparent states.

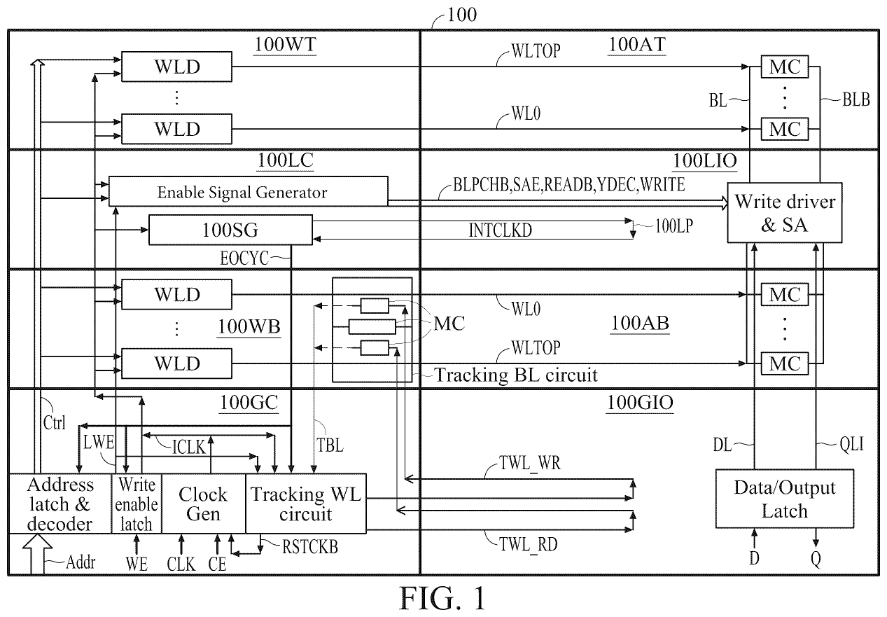

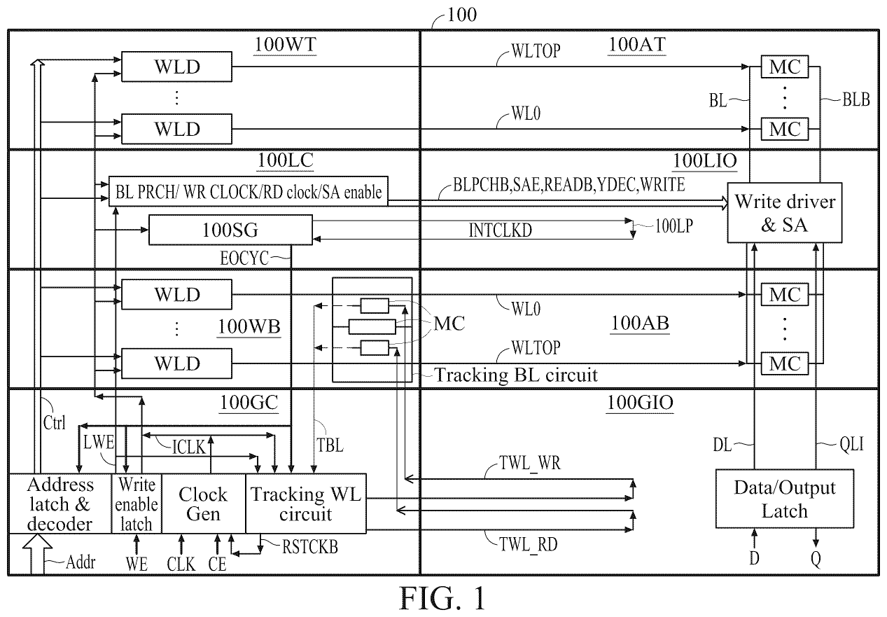

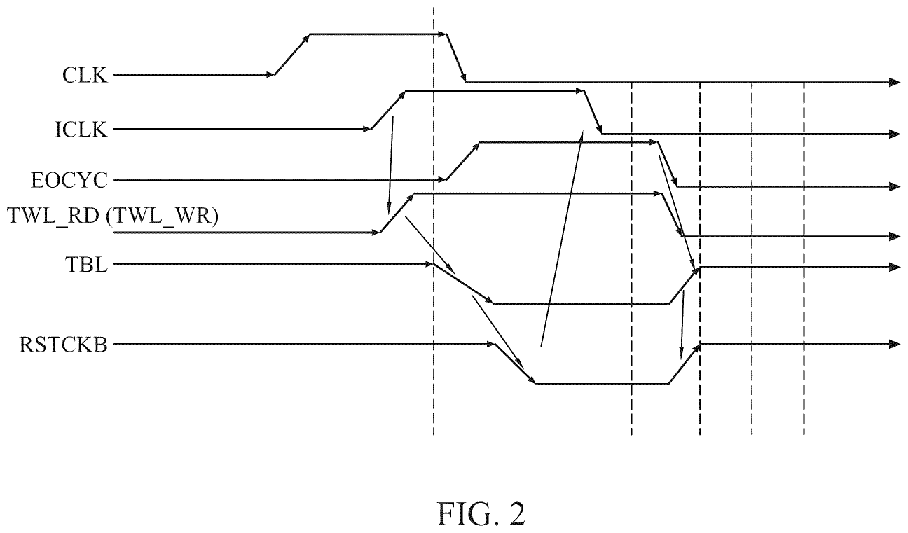

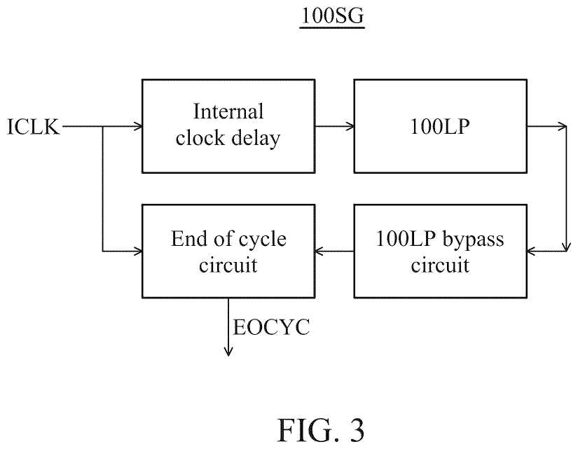

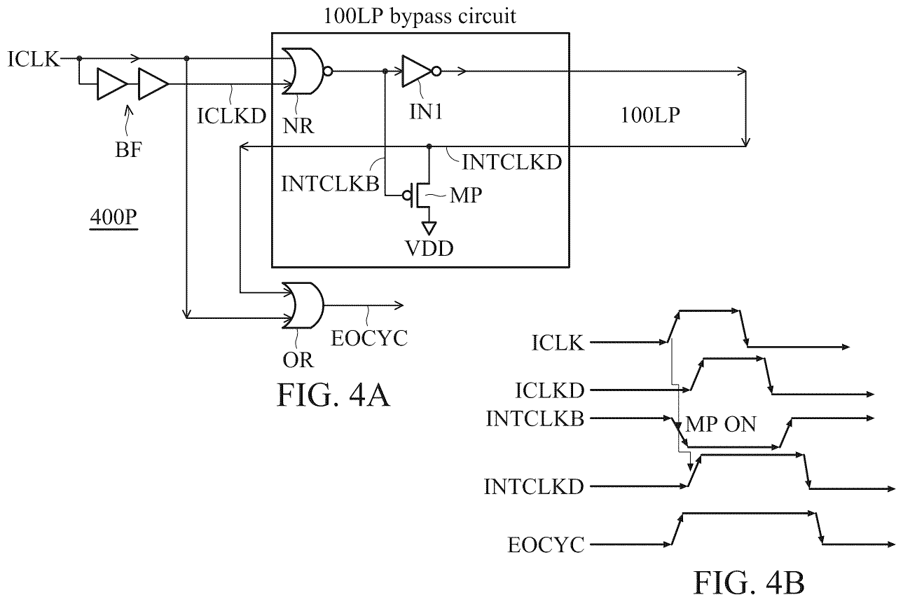

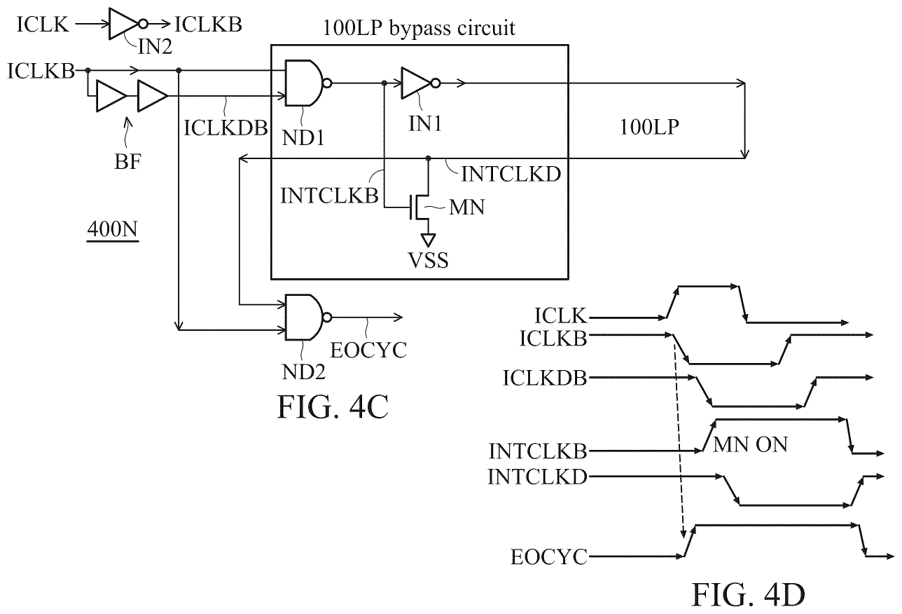

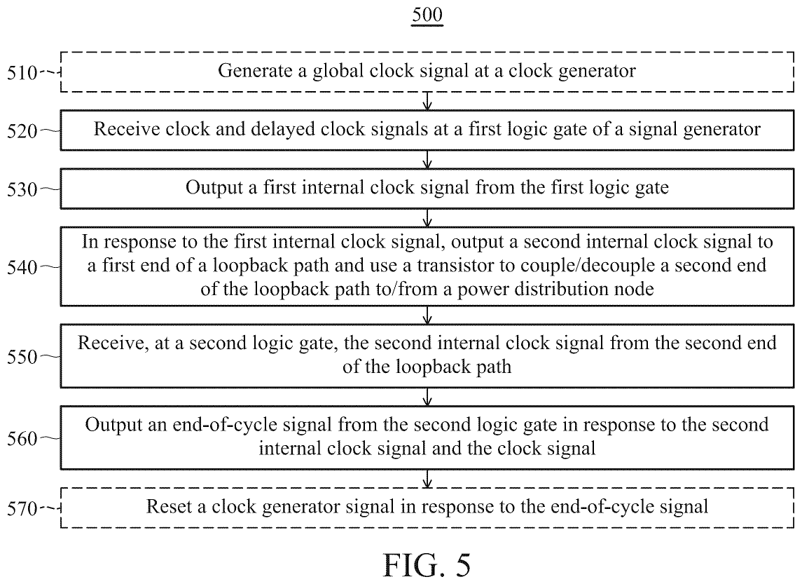

As discussed below, in accordance with some embodiments, FIG. 1 is a schematic diagram of a memory circuit 100 including a signal generator 100SG, FIG. 2 depicts memory circuit 100 operating parameters, FIG. 3 is a block diagram of signal generator 100SG, FIGS. 4A-4D are diagrams related to signal generation circuits 400P and 400N usable at least in part as signal generator 100SG, and FIG. 5 is a flowchart of a method 500 of operating a memory circuit including a signal generator, e.g., memory circuit 100 including signal generator 100SG.

FIG. 1 is a schematic diagram of memory circuit 100, in accordance with some embodiments. Memory circuit 100, also referred to as circuit 100 in some embodiments, is an integrated circuit (IC) including a global control circuit 100GC, a global input/output (I/O) circuit 100GIO, a local control circuit 100LC, a local I/O circuit 100LIO, top and bottom write line driver circuits 100WT and 100WB, and top and bottom memory arrays 100AT and 100AB.

The configuration and number of local control and I/O circuits, write line driver circuits and memory arrays depicted in FIG. 1 are non-limiting examples provided for the purpose of illustration. Configurations and numbers other than those depicted in FIG. 1 are within the scope of the present disclosure.

Global control circuit 100GC is adjacent to and electrically coupled to global I/O circuit 100GIO, and electrically coupled to local control circuit 100LC. Local control circuit 100LC is adjacent to and electrically coupled to local I/O circuit 100LIO, and positioned between and electrically coupled to word line driver circuits 100WT and 100WB. Local I/O circuit 100LIO and word line driver circuit 100WT are both adjacent to and electrically coupled to memory array 100AT, and local I/O circuit 100LIO and word line driver circuit 100WB are both adjacent to and electrically coupled to memory array 100AB. In various embodiments, memory circuit 100 includes combinations of one or more of address lines, bit lines, data lines, word lines, and/or signal lines (depicted in part in FIG. 1) whereby global control circuit 100GC, global I/O circuit 100GIO, local control circuit 100LC, local I/O circuit 100LIO, word line driver circuits 100WT and 100WB, and memory arrays 100AT and 100AB are electrically coupled to each other as discussed.

Two or more circuit elements are considered to be coupled, e.g., electrically coupled, based on one or more direct signal connections and/or one or more indirect signal connections that include one or more logic devices, e.g., an inverter or logic gate, between the two or more circuit elements. In some embodiments, signal communications between the two or more coupled circuit elements are capable of being modified, e.g., inverted or made conditional, by the one or more logic devices.

Memory arrays 100AT and 100AB are arrays of memory cells MC configured to store data. In some embodiments, memory cells MC include static random-access memory (SRAM) cells. In various embodiments, SRAM cells include five-transistor (5T) SRAM cells, six-transistor (6T) SRAM cells, eight-transistor (8T) SRAM cells, nine-transistor (9T) SRAM cells, or SRAM cells having other numbers of transistors. In various embodiments, memory cells MC include dynamic random-access memory (DRAM) cells, non-volatile memory (NVM) cells, or other memory cell types capable of storing data.

Each of global control circuit 100GC, global I/O circuit 100GIO, local control circuit 100LC, local I/O circuit 100LIO, and word line driver circuits 100WT and 100WB is an IC configured to perform a subset of operations whereby data are input to, output from, and stored in corresponding instances of memory cell MC in memory arrays 100AT and 100AB responsive to various combinations of address, clock, control, and/or data signals, e.g., address signal Addr, write enable signal WE, clock signal CLK, and chip enable signal CE depicted in FIG. 1.

Global control circuit 100GC is configured to generate and receive one or more of the address, clock, control, and/or data signals configured to control top-level operation of memory circuit 100; global IO circuit 100GIO is configured to, responsive to one or more of the address, clock, control, and/or data signals, perform top-level I/O operations; local control circuit 100LC is configured to, responsive to one or more of the address, clock, control, and/or data signals, control operation of one or more adjacent instances of local I/O circuit 100LIO and word line driver circuits 100WT and 100WB, thereby controlling diagonally adjacent instances of memory arrays 100AT and 100AB; and each instance of local I/O circuit 100LIO and word line driver circuits 100WT and 100WB is configured to, responsive to one or more of the address, clock, control, and/or data signals, partially control operation of adjacent instances of memory arrays 100AT and 100AB.

In the embodiment depicted in FIG. 1, memory cells MC of a given column of memory cells MC in memory array 100AT or 100AB are coupled to a write driver and sense amplifier (SA) of local I/O circuit 100LIO through bit lines BL and BLB, and the write driver and SA are coupled to a data/output latch of global I/O circuit 100GIO through data lines DL and QLI.

Rows of memory cells MC of memory arrays 100AT and 100AB are coupled to corresponding word line drivers WLD of respective word line driver circuits 100WT and 100WB through word lines WL0-WLTOP. Each instance of word line driver WLD is coupled to an address latch and decoder and clock generator of global control circuit 100GC, and is thereby configured to receive one or more of control signals Ctrl from the address latch and decoder and a clock signal ICLK from the clock generator.

Local control circuit 100LC includes an enable signal generator, e.g., BL PRCH/WR CLOCK/RD clock/SA enable, coupled to the address latch and decoder, clock generator, and a write enable latch of global control circuit 100GC, and to write driver and SA of local I/O circuit 100LIO and is thereby configured to output signals BLPCHB, SAE, READB, YDEC, WRITE to write driver and SA responsive to one or more of control signals Ctrl, a latched write enable signal LWE, and clock signal ICLK.

Local control circuit 100LC also includes signal generator 100SG coupled to the address latch and decoder, write enable latch, clock generator, and a tracking word line (WL) circuit of global control circuit 100GC, and to a loopback path 100LP positioned in local I/O circuit 100LIO. As further discussed below with respect to FIGS. 2-4D, signal generator 100SG is configured to, responsive to clock signal ICLK received from the clock generator, output a signal EOCYC, also referred to as an end-of-cycle signal EOCYC in some embodiments, to each of the address latch and decoder, write enable latch, and tracking WL circuit of global control circuit 100GC, in operation.

Signal EOCYC includes pulses having leading edges based on clock signal ICLK and trailing edges based on a clock signal INTCLKD propagated through loopback path 100LP, as further discussed below. In operation, clock signal INTCLKD being propagated through loopback path 100LP experiences a delay that increases as a length of loopback path 100LP increases. In some embodiments, loopback path 100LP has a length that corresponds to a number of columns of memory cells MC of memory arrays 100AT and 100AB such that delays in clock signal INTCLKD, and the corresponding trailing edges of signal EOCYC pulses, increase as a number of columns of memory cells MC increases.

As discussed below with respect to FIG. 2, memory circuit 100 is configured to, in operation, respond to the trailing edges of signal EOCYC pulses by resetting clock signal ICLK to a logic level corresponding to the beginning of a read and/or write cycle. Memory circuit 100 is thereby configured to perform read and/or write operations having a timing efficiency based on the number of columns of memory arrays 100AT and 100AB.

Global control circuit 100GC includes the address latch and decoder configured to, in operation, output control signals Ctrl responsive to address signal Addr and signal EOCYC, the write enable latch configured to output latched write enable signal LWE responsive to write enable signal WE and signal EOCYC, the clock generator configured to output clock signal ICLK responsive to clock signal CLK, chip enable signal CE, and a reset signal RSTCKB, and the tracking WL circuit configured to output reset signal RSTCKB responsive to latched write enable signal LWE, clock signal ICLK, signal EOCYC, and a tracking signal TBL received from a tracking bit line (BL) circuit coupled to the tracking WL circuit and positioned in word line driver circuit 100WB in the embodiment depicted in FIG. 1.

The tracking WL circuit is coupled to two loopback paths positioned in global I/O circuit 100GIO and having lengths corresponding to word line lengths, e.g., corresponding to a number of columns of memory arrays 100AT and 100AB. The tracking WL circuit is configured to propagate a tracking signal TWL_WR along one loopback path in write operations and a tracking signal TWL_RD along the other loopback path in read operations.

Each loopback path is further coupled to instances of memory cell MC included in the tracking BL circuit. The instances of memory cell MC are configured to, in operation, output tracking signal TBL responsive to each of tracking signals TWL_WR and TWL_RD.

Tracking signal WBL thereby has one or more timing features based on loopback path lengths and/or memory cell MC operating speeds, and the tracking WL circuit is thereby configured to, in operation, output reset signal RSTCKB based on the one or more timing features in combination with the timing of signal EECYC discussed above.

FIG. 2 depicts memory circuit 100 operating parameters, in accordance with some embodiments. FIG. 2 depicts non-limiting examples of clock signals CLK and ICLK, signal EOCYC, tracking signals TWL_RD corresponding to a read operation (or TWL_WR corresponding to a write operation) and TBL, and reset signal RSTCKB. The signals depicted in FIG. 2 are a subset of memory circuit 100 operating parameters and do not include additional signals for the purpose of clarity.

In the embodiment depicted in FIG. 2, a leading edge of a clock signal ICLK pulse is output from the clock generator of global control circuit 100GC in response to a leading edge of a received clock signal CLK pulse. In response to the leading edge of the clock signal ICLK pulse, a leading edge of a signal EOCYC pulse is output from signal generator 100SG and a leading edge of a tracking signal TWL_RD (or TWL_WR) pulse is output from the tracking WL circuit of global control circuit 100GC.

The tracking BL circuit outputs a leading edge of a tracking signal TBL pulse in response to the leading edge of the tracking signal TWL_RD (or TWL_WR) pulse and a trailing edge of the tracking signal TBL pulse in response to a trailing edge of the signal EOCYC pulse. The tracking WL circuit outputs leading and trailing edges of a reset signal RSTCKB pulse in response to the respective leading and trailing edges of the tracking signal TBL pulse, and the clock generator outputs a trailing edge of the clock signal ICLK pulse in response to the leading edge of the tracking signal TBL pulse.

The tracking BL circuit is configured to maintain a logic level (low in the embodiment depicted in FIG. 2) between the leading and trailing edges of the tracking signal TBL pulse based on signal generation circuit 100SG maintaining a logic level (high in the embodiment depicted in FIG. 2) between the leading and trailing edges of the signal EOCYC pulse.

Accordingly, by including signal generator 100SG configured to output the leading edge of the end-of cycle signal EOCYC pulse in response to the leading edge of the clock signal ICLK pulse as discussed below, memory circuit 100 is configured to maintain the integrity of the tracking signal TBL and reset signal RSTCKB pulses compared to other approaches, e.g., those in which a leading edge of an end-of-cycle pulse ns response to an event other than a leading edge of a clock signal pulse.

Unintended circuit operations, e.g., double clocking of clock signal ICLK causing circuit malfunctions and increased latch power consumption, are thereby avoided compared to such other approaches.

FIG. 3 depicts a block diagram of signal generator 100SG, in accordance with some embodiments. Signal generator SG includes an internal clock delay, loopback path 100LP, an end of cycle circuit, and a loopback path 100LP bypass circuit. In some embodiments, e.g., as depicted in FIG. 1, loopback path 100LP is separate from signal generator 100SG, and signal generator 100SG is not considered to include loopback path 100LP.

Each of the internal clock delay and end of cycle circuit are configured to receive clock signal ICLK, the internal clock delay is coupled to a first end of loopback path 100LP, and each of the loopback path 100LP bypass circuit and the end of cycle circuit is coupled to a second end of loopback path 100LP.

In operation, in response to the clock signal ICLK pulse, the internal clock delay outputs an internal clock signal pulse (not shown in FIG. 3) to the first end of loopback path 100LP, and the loopback path 100LP bypass circuit receives the internal clock signal pulse from the second end of loopback path 100LP after being propagated along loopback path 100LP.

The loopback path 100LP bypass circuit is configured to couple the second end of loopback path 100LP to a power distribution node in response to the leading edge of a clock signal ICLK pulse and to decouple the second end of loopback path 100LP from the power distribution node prior to receiving a trailing edge of the internal clock signal pulse.

As further discussed below with respect to the non-limiting examples depicted in FIGS. 4A-4D, signal generator 100SG is thereby configured to output the leading edge of the signal EOCYC pulse in response to the leading edge of the clock signal ICLK pulse so as to be capable of realizing the benefits discussed above.

FIGS. 4A and 4B are a respective schematic diagram and depiction of operating parameters of signal generation circuit 400P, in accordance with some embodiments. Singal generation circuit 400P, also referred to as signal generator 400P in some embodiments, is usable at least in part as signal generator 100SG discussed above with respect to FIGS. 1-3.

As depicted in FIG. 4A, signal generator 400P includes the internal clock delay including a buffer BF, the end of cycle circuit including an OR gate OR, and the loopback 100LP bypass circuit including a NOR gate NR, an inverter IN1 including an output terminal coupled to the first end of loopback path 100LP, and a PMOS transistor MP coupled between the second end of loopback path 100LP and the power distribution node including a power supply voltage node VDD.

In the embodiment depicted in FIG. 4A, buffer BF includes a series of two delay elements gates configured to apply a predetermined delay to clock signal ICLK. In some embodiments, buffer BF is otherwise configured, e.g., by including inverters and/or other numbers of delay elements configured to apply the predetermined delay to clock signal ICLK.

NOR gate NR includes input terminals coupled to each of the input and output terminals of buffer BF, an output terminal coupled to an input terminal of inverter IN1 and a gate of transistor MP.

Transistor MP includes a source/drain (S/D) terminal coupled to the second end of loopback path 100LP and a S/D terminal coupled to power supply voltage node VDD.

OR gate OR includes an input terminal coupled to an input terminal of buffer BF, an input terminal coupled to the second end of loopback path 100LP, and an output terminal that corresponds to an output terminal of signal generator 100SG.

As depicted in FIG. 4B, in operation, buffer BF outputs a delayed clock signal ICLKD in response to clock signal ICLK, NOR gate NR outputs internal clock signal INTCLKB in response to clock signal ICLK and delayed clock signal ICLKD, and inverter IN1 outputs internal clock signal INTCLKB (as inverted, not labeled) to the first end of loopback path 100LP. An internal clock signal INTCLKD is present at the second end of loopback path 100LP.

In response to the leading (rising) edge of the clock signal ICLK pulse, NOR gate NR outputs a falling edge of an internal clock signal INTCLKB pulse, thereby switching on transistor MP and coupling the second end of loopback path 100LP to power supply voltage node VDD. Internal clock signal INTCLKD thereby includes a pulse having a leading (rising) edge prior to a time at which a leading edge of a pulse propagated along loopback path 100LP would otherwise cause internal clock signal INTCLKD to have the leading edge.

In response to either of clock signal ICLK or internal clock signal INTCLKD having a high logic level, OR gate OR outputs signal EOCYC having the high logic level, thereby generating the signal EOCYC pulse having the leading edge in response to the leading edge of the clock signal ICLK pulse and the trailing edge in response to the trailing edge of internal clock signal INTCLKD propagated along loopback path 100LP.

FIGS. 4C and 4D are a respective schematic diagram and depiction of operating parameters of signal generation circuit 400N, in accordance with some embodiments. Singal generation circuit 400N, also referred to as signal generator 400N in some embodiments, is usable at least in part as signal generator 100SG discussed above with respect to FIGS. 1-3.

As depicted in FIG. 4C, signal generator 400N includes the internal clock delay including buffer BF discussed above, the end of cycle circuit including a NAND gate ND2, and the loopback 100LP bypass circuit including a NAND gate ND1, inverter IN1 configured as discussed above, and an NMOS transistor MN coupled between the second end of loopback path 100LP and the power distribution node including a power supply reference node VSS.

Buffer BF is configured to receive clock signal ICLKB complementary to clock signal ICLK discussed above. In some embodiments, signal generator 400N includes an inverter IN2 configured to receive clock signal ICLK and invert and output clock signal ICLK as clock signal ICLKB.

NAND gate ND1 includes input terminals coupled to each of the input and output terminals of buffer BF, an output terminal coupled to an input terminal of inverter IN1 and a gate of transistor MN.

Transistor MN includes a S/D terminal coupled to the second end of loopback path 100LP and a S/D terminal coupled to power supply reference node VSS.

NAND gate ND2 includes an input terminal coupled to an input terminal of buffer BF, an input terminal coupled to the second end of loopback path 100LP, and an output terminal that corresponds to an output terminal of signal generator 100SG.

As depicted in FIG. 4D, in operation, buffer BF outputs a delayed clock signal ICLKDB in response to clock signal ICLKB, NAND gate ND1 outputs internal clock signal INTCLKB in response to clock signal ICLKB and delayed clock signal ICLKDB, and inverter IN1 outputs internal clock signal INTCLKB (as inverted, not labeled) to the first end of loopback path 100LP. Internal clock signal INTCLKD is present at the second end of loopback path 100LP.

In response to the leading (falling) edge of the clock signal ICLKB pulse, NAND gate ND1 outputs a rising edge of an internal clock signal INTCLKB pulse, thereby switching on transistor MN and coupling the second end of loopback path 100LP to power supply reference node VSS. Internal clock signal INTCLKD thereby includes a pulse having a leading (falling) edge prior to a time at which a leading edge of a pulse propagated along loopback path 100LP would otherwise cause internal clock signal INTCLKD to have the leading edge.

In response to either of clock signal ICLKB or internal clock signal INTCLKD having a low logic level, NAND gate ND2 outputs signal EOCYC having the high logic level, thereby generating the signal EOCYC pulse having the leading edge in response to the leading edge of the clock signal ICLKB pulse (as generated from the clock signal ICLK pulse) and the trailing edge in response to the trailing edge of internal clock signal INTCLKD propagated along loopback path 100LP.

As discussed above with respect to FIGS. 4A-4D, each of signal generators 400P and 400N is thereby configured to output end-of-cycle signal EOCYC in accordance with the discussion above with respect to signal generator 100SG and FIGS. 1-3, and a memory circuit, e.g., memory circuit 100, including signal generator 400P or 400N is capable of realizing the benefits discussed above.

FIG. 5 is a flowchart of method 500 of operating a memory circuit, in accordance with some embodiments. Method 500 is usable with a memory circuit, e.g., memory circuit 100 including signal generator 100SG, discussed above with respect to FIGS. 1-4D. In some embodiments, the operations of method 500 are a subset of operations of a method of operating a memory macro.

The sequence in which the operations of method 500 are depicted in FIG. 5 is for illustration only; the operations of method 500 are capable of being executed in sequences that differ from that depicted in FIG. 5. In some embodiments, operations in addition to those depicted in FIG. 5 are performed before, between, during, and/or after the operations depicted in FIG. 5.

At operation 510, in some embodiments, a global clock signal is generated at a clock generator. In some embodiments, generating a global clock signal includes outputting clock signal ICLK from the clock generator of global control circuit 100GC as discussed above with respect to FIG. 1.

At operation 520, clock and delayed clock signals are received at a first logic gate of a signal generator. In some embodiments, receiving the clock and delayed clock signals at the first logic gate includes receiving clock signal ICLK and delayed clock signal ICLKD at NOR gate NR of signal generator 400P discussed above with respect to FIGS. 4A and 4B. In some embodiments, receiving the clock and delayed clock signals at the first logic gate includes receiving clock signal ICLKB and delayed clock signal ICLKDB at NAND gate ND1 of signal generator 400N discussed above with respect to FIGS. 4C and 4D.

At operation 530, a first internal signal is output from the first logic gate based on the clock and delayed clock signals. In some embodiments, outputting the first internal signal from the first logic gate includes outputting internal clock signal INTCLKB from NOR gate NR discussed above with respect to FIGS. 4A and 4B or from NAND gate ND1 discussed above with respect to FIGS. 4C and 4D.

At operation 540, in response to the first internal clock signal, a second internal clock signal is output to a first end of a loopback path and a transistor is used to couple/decouple a second end of the loopback path to/from a power distribution node.

In some embodiments, outputting the second internal clock signal includes using inverter IN1 to invert and output internal clock signal INTCLKB to the first end of loopback path 100LP as discussed above with respect to FIGS. 4A-4D.

In some embodiments, using the transistor to couple/decouple the second end of the loopback path to/from the power distribution node includes using transistor MP to couple/decouple the second end of loopback path 100LP to/from power supply voltage node VDD as discussed above with respect to FIGS. 4A and 4B.

In some embodiments, using the transistor to couple/decouple the second end of the loopback path to/from the power distribution node includes using transistor MN to couple/decouple the second end of loopback path 100LP to/from power supply reference node VSS as discussed above with respect to FIGS. 4C and 4D.

At operation 550, the second internal clock signal is received from the second end of the loopback path at a second logic gate. In some embodiments, receiving the second internal clock signal from the second end of the loopback path at the second logic gate includes receiving internal clock signal INTCLKD from the second end of loopback path 100LP at OR gate OR discussed above with respect to FIGS. 4A and 4B or at NAND gate ND2 discussed above with respect to FIGS. 4C and 4D.

At operation 560, an end-of-cycle signal is output from the second logic gate in response to the second internal clock signal and the clock signal. In some embodiments, outputting the end-of-cycle signal includes outputting signal EOCYC based on internal clock signal INTCLKD and clock signal ICLK from OR gate OR discussed above with respect to FIGS. 4A and 4B or from NAND gate ND2 discussed above with respect to FIGS. 4C and 4D.

At operation 570, a clock generator is reset in response to the end-of-cycle signal. In some embodiments, resetting the clock signal includes using the clock generator of global control circuit 100GC to reset clock signal ICLK based on reset signal RSTCKB in response to signal EOCYC as discussed above with respect to FIGS. 1 and 2.

By executing some or all of the operations of method 500, a signal generation circuit of a memory circuit outputs a leading edge of an end-of-cycle signal pulse in response to the leading edge of a received clock signal pulse and is thereby capable of realizing the benefits discussed above with respect to signal generation circuit 100SG.

In some embodiments, a signal generation circuit includes a loopback path and a signal generator including an inverter including an output terminal coupled to a first end of the loopback path, a transistor coupled between a second end of the loopback path and a power distribution node, a buffer including an input terminal configured to receive a clock signal, a first logic gate including a first input terminal coupled to the buffer input terminal, a second input terminal coupled to an output terminal of the buffer, and an output terminal coupled to an input terminal of the inverter and a gate of the transistor, and a second logic gate including a first input terminal coupled to the buffer input terminal, a second input terminal coupled to the second end of the loopback path, and an output terminal configured to output an output signal. In some embodiments, the loopback path is positioned in a local I/O circuit of a memory circuit and the signal generator is positioned in a local control circuit of the memory circuit. In some embodiments, the loopback path has a length corresponding to a number of columns of memory cells of a memory cell array of the memory circuit. In some embodiments, the transistor includes a p-type transistor, the power distribution node includes a power supply voltage node, the first logic gate includes a NOR gate, and the second logic gate includes an OR gate. In some embodiments, the transistor includes an n-type transistor, the power distribution node includes a power supply reference node, and each of the first and second logic gates includes a NAND gate. In some embodiments, the signal generator includes a clock signal inverter including an output terminal coupled to the buffer input terminal. In some embodiments, the output terminal of the second logic gate is coupled to a tracking circuit.

In some embodiments, a memory circuit includes a global control circuit including a clock generator, a local I/O circuit including a loopback path positioned between first and second memory arrays, and a local control circuit coupled to each of the global control circuit and the local I/O circuit, wherein the local control circuit includes a signal generator including an inverter including an output terminal coupled to a first end of the loopback path, a transistor coupled between a second end of the loopback path and a power distribution node of the memory circuit, a buffer including an input terminal coupled to the clock generator, a first logic gate including a first input terminal coupled to the buffer input terminal, a second input terminal coupled to an output terminal of the buffe, and an output terminal coupled to an input terminal of the inverter and a gate of the transistor, and a second logic gate including a first input terminal coupled to the buffer input terminal, a second input terminal coupled to the second end of the loopback path, and an output terminal coupled to the global control circuit. In some embodiments, the loopback path has a length corresponding to a number of columns of memory cells of each of the first and second memory arrays. In some embodiments, the memory cells of each of the first and second memory arrays include 6T SRAM memory devices. In some embodiments, the transistor of the signal generator includes a p-type transistor, the power distribution node of the memory circuit includes a power supply voltage node of the memory circuit, the first logic gate of the signal generator includes a NOR gate, and the second logic gate of the signal generator includes an OR gate. In some embodiments, the transistor of the signal generator includes an n-type transistor, the power distribution node of the memory circuit includes a power supply reference node of the memory circuit, and each of the first and second logic gates of the signal generator includes a NAND gate. In some embodiments, the buffer input terminal is coupled to the clock generator of the global control circuit through a clock signal inverter. In some embodiments, the output terminal of the second logic gate of the signal generator is coupled to each of a tracking circuit, a write enable latch, and an address decoder of the global control circuit.

In some embodiments, a method of generating a memory circuit signal includes receiving a clock signal and a delayed clock signal at a first logic gate of a signal generator, outputting, from the first logic gate, a first internal clock signal based on the clock signal and the delayed clock signal, in response to the first internal clock signal, outputting a second internal clock signal from an inverter of the signal generator to first end of a loopback path coupled to the signal generator and using a transistor to couple and decouple a second end of the loopback path to and from a power distribution node, receiving, at a second logic gate, the second internal clock signal from the second end of the loopback path, and the clock signal, and outputting the memory circuit signal from the second logic gate in response to the second internal clock signal and the clock signal. In some embodiments, receiving the clock and delayed clock signals at the first logic gate of the signal generator includes operating the signal generator of a local control circuit of the memory circuit, and outputting and receiving the second internal clock signal to and from the loopback path includes propagating the second internal clock signal through the loopback path positioned in a local I/O circuit of the memory circuit coupled to the local control circuit. In some embodiments, receiving the clock and delayed clock signals at, and outputting the first internal clock signal from, the first logic gate includes receiving the clock and delayed clock signals at, and outputting the first internal clock signal from, a NOR gate, using the transistor to couple and decouple the second end of the loopback path to and from the power distribution node includes using a p-type transistor to couple and decouple the second end of the loopback path to and from a power supply voltage node, and receiving the second internal clock signal and the clock signal at, and outputting the memory circuit signal from, the second logic gate includes receiving the second internal clock signal and the clock signal at, and outputting the memory circuit signal from, an OR gate. In some embodiments, receiving the clock and delayed clock signals at, and outputting the first internal clock signal from, the first logic gate includes receiving the clock and delayed clock signals at, and outputting the first internal clock signal from, a first NAND gate, using the transistor to couple and decouple the second end of the loopback path to and from the power distribution node includes using an n-type transistor to couple and decouple the second end of the loopback path to and from a power supply reference node, and receiving the second internal clock signal and the clock signal at, and outputting the memory circuit signal from, the second logic gate includes receiving the second internal clock signal and the clock signal at, and outputting the memory circuit signal from, a second NAND gate. In some embodiments, receiving the clock and delayed clock signals at the first logic gate includes using an inverter to generate the clock signal from a global clock signal of the memory circuit. In some embodiments, outputting the memory circuit signal from the second logic gate includes outputting the memory circuit signal to each of a tracking circuit, a write enable latch, and an address decoder of the memory circuit.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A signal generation circuit comprising:
a loopback path; and
a signal generator comprising:
an inverter comprising an output terminal coupled to a first end of the loopback path;
a transistor coupled between a second end of the loopback path and a power distribution node;
a buffer comprising an input terminal configured to receive a clock signal;
a first logic gate comprising:
a first input terminal coupled to the buffer input terminal;
a second input terminal coupled to an output terminal of the buffer; and
an output terminal coupled to an input terminal of the inverter and a gate of the transistor; and
a second logic gate comprising:
a first input terminal coupled to the buffer input terminal;
a second input terminal coupled to the second end of the loopback path; and
an output terminal configured to output an output signal.

2. The signal generation circuit of claim 1, wherein
the loopback path is positioned in a local input/output (I/O) circuit of a memory circuit; and
the signal generator is positioned in a local control circuit of the memory circuit.

3. The signal generation circuit of claim 2, wherein
the loopback path has a length corresponding to a number of columns of memory cells of a memory cell array of the memory circuit.

4. The signal generation circuit of claim 1, wherein
the transistor comprises a p-type transistor,
the power distribution node comprises a power supply voltage node,
the first logic gate comprises a NOR gate, and
the second logic gate comprises an OR gate.

5. The signal generation circuit of claim 1, wherein
the transistor comprises an n-type transistor,
the power distribution node comprises a power supply reference node, and
each of the first and second logic gates comprises a NAND gate.

6. The signal generation circuit of claim 5, wherein
the signal generator further comprises a clock signal inverter comprising an output terminal coupled to the buffer input terminal.

7. The signal generation circuit of claim 1, wherein
the output terminal of the second logic gate is coupled to a tracking circuit.

8. A memory circuit comprising:
a global control circuit comprising a clock generator;
a local input/output (I/O) circuit comprising a loopback path positioned between first and second memory arrays; and
a local control circuit coupled to each of the global control circuit and the local I/O circuit, wherein the local control circuit comprises a signal generator comprising:
an inverter comprising an output terminal coupled to a first end of the loopback path;
a transistor coupled between a second end of the loopback path and a power distribution node of the memory circuit;
a buffer comprising an input terminal coupled to the clock generator;
a first logic gate comprising:
a first input terminal coupled to the buffer input terminal;
a second input terminal coupled to an output terminal of the buffer; and
an output terminal coupled to an input terminal of the inverter and a gate of the transistor; and
a second logic gate comprising:
a first input terminal coupled to the buffer input terminal;
a second input terminal coupled to the second end of the loopback path; and
an output terminal coupled to the global control circuit.

9. The memory circuit of claim 8, wherein
the loopback path has a length corresponding to a number of columns of memory cells of each of the first and second memory arrays.

10. The memory circuit of claim 9, wherein
the memory cells of each of the first and second memory arrays comprise six-transistor static random-access memory (SRAM) memory devices.

11. The memory circuit of claim 8, wherein
the transistor of the signal generator comprises a p-type transistor,
the power distribution node of the memory circuit comprises a power supply voltage node of the memory circuit,
the first logic gate of the signal generator comprises a NOR gate, and
the second logic gate of the signal generator comprises an OR gate.

12. The memory circuit of claim 8, wherein
the transistor of the signal generator comprises an n-type transistor,
the power distribution node of the memory circuit comprises a power supply reference node of the memory circuit, and
each of the first and second logic gates of the signal generator comprises a NAND gate.

13. The memory circuit of claim 12, wherein
the buffer input terminal is coupled to the clock generator of the global control circuit through a clock signal inverter.

14. The memory circuit of claim 8, wherein
the output terminal of the second logic gate of the signal generator is coupled to each of a tracking circuit, a write enable latch, and an address decoder of the global control circuit.

15. A method of generating a memory circuit signal, the method comprising:
receiving a clock signal and a delayed clock signal at a first logic gate of a signal generator;
outputting, from the first logic gate, a first internal clock signal based on the clock signal and the delayed clock signal;
in response to the first internal clock signal,
outputting a second internal clock signal from an inverter of the signal generator to first end of a loopback path coupled to the signal generator, and
using a transistor to couple and decouple a second end of the loopback path to and from a power distribution node;
receiving, at a second logic gate, the second internal clock signal from the second end of the loopback path, and the clock signal; and
outputting the memory circuit signal from the second logic gate in response to the second internal clock signal and the clock signal.

16. The method of claim 15, wherein
the receiving the clock and delayed clock signals at the first logic gate of the signal generator comprises operating the signal generator of a local control circuit of the memory circuit, and
the outputting and receiving the second internal clock signal to and from the loopback path comprises propagating the second internal clock signal through the loopback path positioned in a local input/output (I/O) circuit of the memory circuit coupled to the local control circuit.

17. The method of claim 15, wherein
the receiving the clock and delayed clock signals at, and outputting the first internal clock signal from, the first logic gate comprises receiving the clock and delayed clock signals at, and outputting the first internal clock signal from, a NOR gate,
the using the transistor to couple and decouple the second end of the loopback path to and from the power distribution node comprises using a p-type transistor to couple and decouple the second end of the loopback path to and from a power supply voltage node, and
the receiving the second internal clock signal and the clock signal at, and outputting the memory circuit signal from, the second logic gate comprises receiving the second internal clock signal and the clock signal at, and outputting the memory circuit signal from, an OR gate.

18. The method of claim 15, wherein
the receiving the clock and delayed clock signals at, and outputting the first internal clock signal from, the first logic gate comprises receiving the clock and delayed clock signals at, and outputting the first internal clock signal from, a first NAND gate,
the using the transistor to couple and decouple the second end of the loopback path to and from the power distribution node comprises using an n-type transistor to couple and decouple the second end of the loopback path to and from a power supply reference node, and
the receiving the second internal clock signal and the clock signal at, and outputting the memory circuit signal from, the second logic gate comprises receiving the second internal clock signal and the clock signal at, and outputting the memory circuit signal from, a second NAND gate.

19. The method of claim 15, wherein
the receiving the clock and delayed clock signals at the first logic gate comprises using an inverter to generate the clock signal from a global clock signal of the memory circuit.

20. The method of claim 15, wherein
the outputting the memory circuit signal from the second logic gate comprises outputting the memory circuit signal to each of a tracking circuit, a write enable latch, and an address decoder of the memory circuit.
